(19) United States
(12) Patent Application Publication
(10) Pub. No.: US 2008/0290892 A1
(43) Pub. Date: Nov. 27, 2008

(54) EVALUATION DEVICE AND EVALUATION METHOD USING EVALUATION DEVICE

(75) Inventors: Toru TAKEGUCHI, Chiyoda-ku (JP); Kaoru Motonami, Chiyoda-ku (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, Chiyoda-ku (JP)

(21) Appl. No.: 11/946,426

(22) Filed: Nov. 28, 2007

(30) Foreign Application Priority Data
Dec. 14, 2006 (JP) 2006-336942

(51) Int. Cl. G01R 31/26

(52) U.S. Cl. 324/769

(57) ABSTRACT

In an evaluation device a plurality of evaluation cells, a signal wiring for applying a voltage to the evaluation cells, and an output terminal pad for a signal taking out wiring for measuring outputs from the evaluation cells through a signal taking out wiring are provided on an insulating substrate. Thus, the in-plane distribution of electric characteristics can be easily measured. Further, the electric characteristics related to the particle diameter of the crystal of a poly-crystal silicon film are evaluated so that the in-plane unevenness of the particle diameter of the crystal of the poly-crystal silicon film can be managed.

This application claims priority from Japanese Patent Application No. 2006-336942 filed on Dec. 14, 2006, the entire subject matter of which is incorporated herein by reference.

### BACKGROUND OF THE INVENTION

1. Field of the Invention

The present invention relates to an evaluation device and an evaluation method using the evaluation device for evaluating the quality of the film of a poly-crystal semiconductor film obtained by applying a laser beam to an amorphous semiconductor film.

2. Description of the Related Art

A liquid crystal display device (LCD) as one of usual ordinary thin panels has features of a low consumed electric power or lightness. The LCD has been widely used as a monitor of a personal computer or a monitor of a portable information terminal device by taking advantage of such features. Further, in recent years, the LCD has been also widely employed as the use of a TV in place of a usual cathode ray tube. However, the LCD has problems that an angle of visibility or a contrast is limited or a high speed response for meeting a moving image is hardly followed. As a device for a thin panel of a next generation that clears these problems, an EL display device has been employed. This is an electro-luminescence type EL display device having light emitting elements such as EL elements used in a pixel display part. In such a way, the EL display device has features such as a self-light emitting type, a wide angle of visibility, a high contrast, a high speed response or the like that are not provided in the LCD.

In these display devices, as a switching element, a thin film transistor (TFT) is used. As the TFT, an MOS structure using a semiconductor film is frequently used. The TFT includes kinds of an inverted stagger type or a top gate type. The semiconductor thin film includes an amorphous semiconductor film or a poly-crystal semiconductor film. They are suitably selected depending on the use or the performance of the display device. In a small panel, the poly-crystal semiconductor film is frequently used. The TFT using the poly-crystal semiconductor film advantageously has a mobility about 100 times higher than that of the TFT using the amorphous semiconductor film. Thus, the TFT including the poly-crystal semiconductor film is used not only as a pixel switching element, but also as a peripheral driving circuit, so that a TFT-LCD formed integrally with a driving circuit has been developed in which the TFT of a pixel and the TFT of the driving circuit are simultaneously formed on the same substrate.

As a method for forming the poly-crystal semiconductor film, a method has been known that the amorphous semiconductor film is initially formed on an upper layer of a silicon dioxide (SiO₂) film formed as a substrate film, and then, the amorphous semiconductor film is irradiated with, for example, a laser beam to poly-crystallize the semiconductor film (for example, JP-A-2003-17505 (FIG. 1)).

A method for producing the TFT after the poly-crystal semiconductor film is formed is also known. Specifically, a gate insulating film made of SiO₂ is formed on the poly-crystal semiconductor film patterned to a desired form to form a gate electrode. Then, impurities such as phosphorus P or boron B are introduced to the poly-crystal semiconductor film through the gate insulating film to form source and drain areas. Further, the source and drain areas are electric conductive areas including the impurities of the poly-crystal semiconductor film. Subsequently, a source electrode is connected to the source area and a drain electrode is connected to the drain area. Here, an area that is sandwiched in between the source and drain areas and to which the impurities are not introduced is a channel area. After that, an interlayer insulating film is formed so as to cover the gate electrode and the gate insulating film. Then, contact holes reaching the source and drain areas of the poly-crystal semiconductor film are opened to the interlayer insulating film and the gate insulating film. A metal film is formed on the interlayer insulating film and patterned to be connected to the source and drain areas formed in the poly-crystal semiconductor film through the contact holes to form source and drain electrodes. In such a way, the TFT is formed. After that, a pixel electrode or an EL element is formed so as to be connected to the drain electrode so that a display device is formed.

A correlation appears between the particle diameter of a crystal of the poly-crystal semiconductor film and the characteristics of the TFT formed by using the poly-crystal semiconductor film. For example, when the particle diameter is larger, a mobility is apt to be improved. Therefore, it is important to precisely grasp the particle diameter of the crystal. Usually, to know the size of the particle diameter of the crystal, after a grain boundary is selectively removed by etching such as a secco etching process, the particle diameter is measured by using a scanning type electron microscope (SEM) or observing or measuring the particle diameter of the crystal by using an atomic force microscope (AFM) (for example, JP-A-2000-31229 (page 2)). These methods are used to observe an actual crystal so that the particle diameter of the crystal of a formed poly-crystal semiconductor film can be precisely evaluated. Further, the electric characteristics of the TFT as a simple substance formed by using the poly-crystal semiconductor film are measured to evaluate the electric characteristics such as the mobility, an on-current, a sharpness, or the like so that whether or not the desired film quality of the poly-crystal semiconductor film is obtained is evaluated (for example, JP-A-2001-308336 (FIG. 1)).

However, in such methods, a representative particle diameter of a crystal or TFT characteristics in a micro area of about several to several ten μm² at most are understood, however, it is difficult to grasp the stability or the unevenness of the particle diameter of the crystal or the electric characteristics in a wide area of several cm or more necessary for forming the display device.

When the known laser irradiation method is applied to the amorphous semiconductor film to form the poly-crystal semiconductor film, a structure is obtained that crystals having various sizes of about 0.1 to 1.0 μm are arranged. This is considered to result from one of causes that a laser is affected by the influences of the aberration or the very small polishing flaws of a lens used in an optical system or the mutual interference of laser beams or an extremely fine output variation of an oscillator in a laser scanning direction to have a distribution in an energy radiation density.

When the poly-crystal semiconductor film having the above-described various particle sizes of the crystals is used to form the TFT, an unevenness in the particle diameters of the crystals is a factor for generating an unevenness in the TFT characteristics. This phenomenon is generated, because the sizes or the numbers of the crystal particles respectively existing in the channels in the TFTs are different depending on positions where the TFTs are arranged. The TFT characteristics are affected thereby. When the TFT having the unevenness in characteristics is used in the pixel or the peripheral driving circuit, unevenness arises in voltage or current written in the pixels respectively. This is visually recognized as an unevenness in display to deteriorate display characteristics.

Accordingly, not only to determine laser applying conditions, but also to manage a laser annealing device such as an adjustment of an optical system, a unit is necessary for grasping the particle diameter of the crystal or the TFT characteristics in a usual micro area, and evaluating the film quality of the poly-crystal semiconductor film in an area of a wide range.

### SUMMARY OF THE INVENTION

The present invention has been made to solve the above-described problems. An object of the present invention is to provide a device that can electrically evaluate the film quality of a poly-crystal semiconductor film formed by applying a laser beam to an amorphous semiconductor film formed on an insulating substrate in an area of a wide range and can evaluate the stability or the unevenness of the film quality.

An evaluation device of the present invention includes: a substrate; a plurality of elements arranged on the substrate and respectively having thin film transistors; a first wiring that applies an electric signal to the elements respectively; a second wiring that takes out electric outputs respectively from the elements; and a scanning wiring, and is characterized in that the thin film transistors are respectively electrically connected to the first wiring, the second wiring and the scanning wiring so that the elements are respectively connected together and terminal pads extending from the second wiring are provided on the substrate.

According to the present invention, the electric outputs outputted from the elements to which the electric signal is applied are measured so that the distribution of the characteristics of the elements respectively in the surface of the substrate can be measured. For example, the present invention can be also applied to an electrical evaluation of the stability or the unevenness of the film quality of a semiconductor film that is poly-crystallized by applying a laser beam to an amorphous semiconductor film formed on an insulating substrate throughout an area of a wide range.

### BRIEF DESCRIPTION OF THE DRAWINGS

FIG. 1 is a block diagram showing an evaluation device according to an embodiment;

FIG. 2 is an equivalent circuit diagram showing the evaluation device of a poly-crystal semiconductor thin film according to the embodiment;

FIG. 3 is an equivalent circuit diagram showing the structure of an evaluation cell according to a first embodiment;

FIG. 4 is a sectional view of a thin film transistor forming the evaluation cell according to the first embodiment;

FIG. 5 is a diagram showing evaluated results obtained by the first embodiment;

FIG. 6 is a schematic sectional view showing a method for producing the thin film transistor forming the evaluation cell according to the first embodiment;

FIG. 7 is a schematic sectional view showing a method for producing the thin film transistor forming the evaluation cell according to the first embodiment;

FIG. 8 is an equivalent circuit diagram showing the structure of an evaluation cell according to a second embodiment;

FIG. 9 is a sectional view showing a thin film transistor and a capacity element forming the evaluation cell according to the second embodiment;

FIG. 10 is a diagram for explaining an evaluation method according to the second embodiment; and

FIG. 11 is a diagram showing evaluated results obtained by the second embodiment.

### DETAILED DESCRIPTION OF THE PREFERRED EMBODIMENTS

### First Embodiment

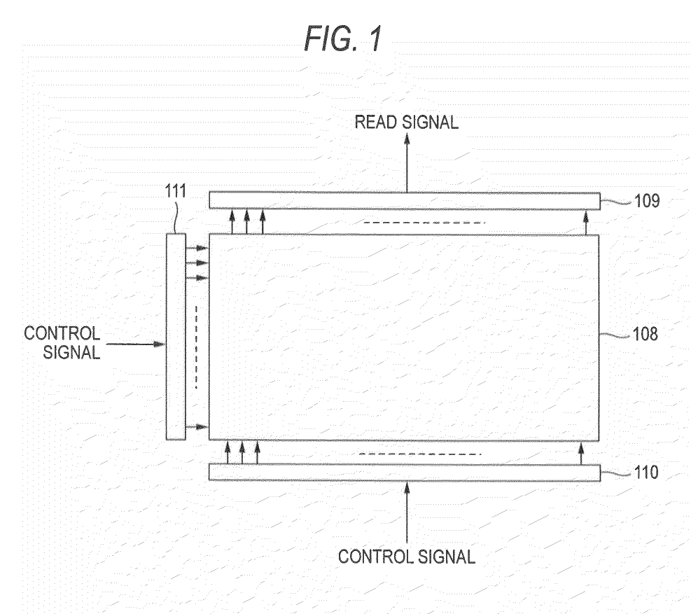

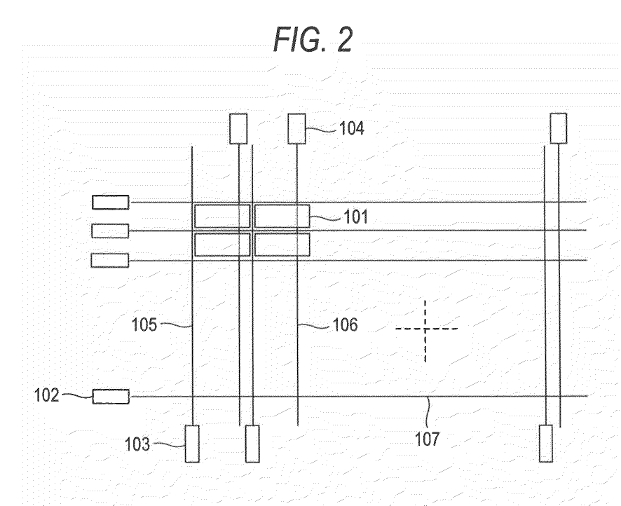

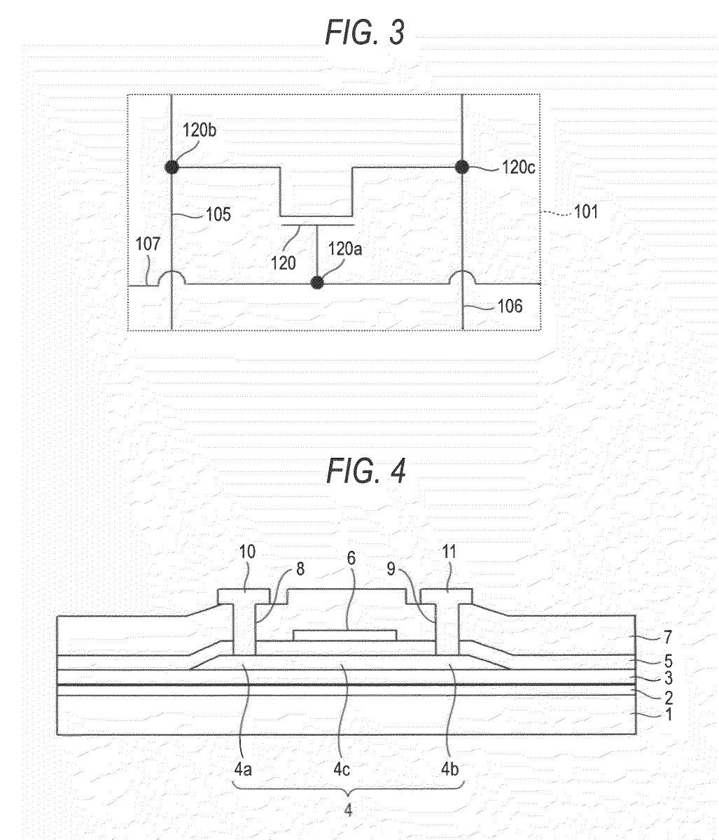

Now, an evaluation device according to a first embodiment will be described below by referring to the drawings. FIG. 1 is a block diagram showing the evaluation device according to the first embodiment. FIG. 2 is an equivalent circuit diagram showing the structure of the evaluation device according to the first embodiment. FIG. 3 is an equivalent circuit diagram showing an evaluation cell forming the evaluation device according to the first embodiment.

Initially, by referring to FIG. 1, the evaluation device is described. The evaluation device according to the first embodiment is formed on an insulating substrate 1 and includes an evaluation cell arranging area 108 in which the evaluation cells as elements are arranged, a signal wiring decoder 110 for outputting a signal voltage applied to the evaluation cells respectively in the evaluation cell arranging area 108, a signal output buffer 109 for reading currents respectively outputted from the evaluation cells and a scanning wiring decoder 111 for applying a voltage to select the evaluation cell whose electric characteristics are measured.

Now, a detail of the evaluation cell arranging area 108 in which the evaluation cells are arranged will be described by referring to FIG. 2. In the evaluation cell arranging area 108, an output terminal pad 104 for a signal taking out wiring connected to the signal output buffer 109, an input pad 103 for a signal wiring connected to the signal wiring decoder 110 and an input terminal pad 102 for a scanning wiring connected to the scanning wiring decoder 111 are formed. Circuits for externally selecting arbitrary scanning wiring and signal wiring are electrically connected respectively to the terminal pads and a circuit for reading a signal is connected to the output terminal pad 104 for the signal taking out wiring.

Then, a signal wiring 105 as a first wiring extending from the input pad 103 for the signal wiring and a signal taking out wiring 106 as a second wiring extending from the output terminal pad 104 for the signal taking out wiring are formed so as to longitudinally extend in the evaluation cell arranging area 108. Further, a scanning wiring 107 extending from the input terminal pad 102 for the scanning wiring is formed so as to horizontally extend in the evaluation cell arranging area 108. That is, in the scanning wiring 107, the signal wiring 105 and the signal taking out wiring 106, the terminal pads for inputting and outputting signals from external parts are respectively provided.

Accordingly, the scanning wiring 107 is formed so as to intersect at right angles to the signal wiring 105 and the signal taking out wiring 106. The evaluation cells 101 are respectively formed in the vicinity of parts intersecting at right angles with the wiring and the evaluation cells are respectively connected to the scanning wiring 107, the signal wiring 105 and the signal taking out wiring 106. That is, the evaluation cells are respectively connected together by these wiring. In FIG. 2, the evaluation cells 101 are formed in the shape of a matrix of a plurality of rows x a plurality of columns, however, they may be arranged in one row or one-dimensionally arranged.

Now, the structure of the evaluation cell 101 will be described by referring to FIG. 3. The first embodiment is characterized in that a thin film transistor 120 is used as the evaluation cell. In FIG. 3, the thin film transistor 120 includes a gate terminal 120a, a source terminal 120b and a drain terminal 120c that are respectively connected to the scanning wiring 107, the signal wiring 105 and the signal taking out wiring 106.

Accordingly, a voltage outputted from the scanning wiring decoder 111 is applied to the gate terminal 120a in the evaluation cell 101 through the input terminal pad 102 for the scanning wiring and the scanning wiring 107. The thin film transistor 120 having the gate terminal 120a to which the voltage is applied is turned on. At this time, when a voltage outputted from the signal wiring decoder 110 is applied to the source terminal 120b through the signal wiring 105, a voltage meeting the characteristics of the thin film transistor 120 is outputted to the signal output buffer 109 through the signal taking out wiring 106.

The thin film transistor 120 may be either an inverted stagger type or a top gate type. Now, the structure of the top gate type thin film transistor will be described below. FIG. 4 is a sectional view of the thin film transistor 120 used as the evaluation cell 101 in the first embodiment.

A poly-crystal semiconductor film 4 such as poly-silicon is formed on an upper layer having an SiN film 2 and an SiO2 film 3 laminated on an insulating substrate 1. The poly-crystal semiconductor film 4 is obtained in such a way that an amorphous semiconductor film is formed and then poly-crystallized by a well-known laser annealing method. Further, the poly-crystal semiconductor film 4 includes a source area 4a and a drain area 4b with a resistance lowered by introducing impurities and a channel area 4c sandwiched in between the source area 4a and the drain area 4b to which the impurities are not introduced.

A gate insulating film 5 is formed so as to cover the poly-crystal semiconductor film 4 and a gate electrode 6 is formed so as to be opposed to the channel area 4c through the gate insulating film 5. This gate electrode 6 is electrically connected to the scanning wiring 107. On the gate electrode 6, an interlayer insulating film 7 is formed. The interlayer insulating film 7 is provided with contact holes 8 and 9 connected to the source area 4a and the drain area 4b. On the interlayer insulating film 7, a source electrode 10 and a drain electrode 11 are formed and respectively connected to the source area 4a and the drain area 4b through the contact holes 8 and 9. Though not shown in the drawing, the gate electrode 6 and the source electrode 10 respectively correspond to the gate terminal 120a and the source terminal 120b and are connected to the scanning wiring 107 and the signal wiring 105. Similarly, the drain electrode 11 corresponds to the drain terminal 120c and is electrically connected to the signal taking out wiring 106.

In the first embodiment, as an element forming the evaluation cell 101, the thin film transistor 120 that is formed by using a semiconductor film poly-crystallized by applying a laser beam to the amorphous semiconductor film 4 is employed as a component element of the evaluation cell. In the first embodiment, the thin film transistor 120 has a size that a channel length is 5 μm and a channel width is 10 μm. However, the size of the thin film transistor 120 is not limited to the above-described size.

The evaluation device according to the first embodiment includes a plurality of evaluation cells arranged on the insulating substrate and respectively having thin film transistors; a first wiring that applies an electric signal to the evaluation cells respectively; a second wiring that takes out electric outputs respectively from the evaluation cells; and a scanning wiring. The plurality of the thin film transistors are respectively electrically connected to the first wiring, the second wiring and the scanning wiring so that the evaluation cells are respectively connected together. Further, terminal pads for taking out the electric outputs that extend from the second wiring are provided on the insulating substrate.

Accordingly, since an arbitrary evaluation cell can be selected from the plurality of the evaluation cells and the electric characteristics thereof can be taken out to an external part through the terminal pad, the in-plane distribution of the electric characteristics of the evaluation cells in the evaluation cell arranging area 108 can be measured. Especially, when the evaluation cells are arranged in the shape of the matrix of the plurality of rows x the plurality of columns, the unevenness of the electric characteristics can be evaluated over a wide range on the substrate. Thus, a design or a production process can be optimized on the basis of the obtained evaluated results so that a display device excellent in its quality of display can be obtained.

In such a structure, when a voltage is applied from the signal input terminal pads of the scanning wiring and the signal wiring connected to the evaluation cell located in an area where the quality of the film is desired to be evaluated, a current is supplied to the signal taking out wiring. A current value outputted from the signal taking out wiring is read, so that this can be applied to, for example, a method for evaluating the film quality of the poly-crystal semiconductor film and an in-plane distribution thereof.

Now, a specific example of an evaluation method using the evaluation device in the first embodiment will be described below. A voltage of Vd₁ (V) is applied to the signal wiring 105 connected to the evaluation cell 101 located in the area where the film quality is desired to be evaluated from the input terminal pad 103 for the signal wiring. Further, a voltage of Vg₁ (V) is applied to the scanning wiring 107 of the evaluation cell 101 from the input terminal pad 102 for the scanning wiring, so that the thin film transistor 120 formed in the evaluation cell 101 is turned to supply a current.

At this time, a current value i₁ is read from the connected signal taking out wiring 106. Further, a voltage of Vg₂ (V) is applied to the scanning wiring 107 of the evaluation cell 101 from the input terminal pad 102 for the scanning wiring to read a current value i₂ by the same method as that of the current value i₁. That is, when voltages of a plurality of voltage values are applied to the thin film transistor 120 to which the voltage is applied through the signal wiring 105 through the scanning wiring 107, electric signals such as currents outputted from the evaluation cell 101 respectively relative to the voltages are measured through the signal taking out wiring 106. The variation (i₂−i₁) of the current values indicates an index sk showing the sharpness of the thin film transistor 120 in gate voltages Vg₁ to Vg₂ (V). Namely, for the evaluation cells respectively arranged in the evaluation cell arranging area 108,

sk=(i₂−i₁)/(Vg₂−Vg₁) [Equation 1]

is obtained to compare and evaluate the difference Δsk of sk of the adjacent evaluation cells or the equality of the arranged evaluation cells.

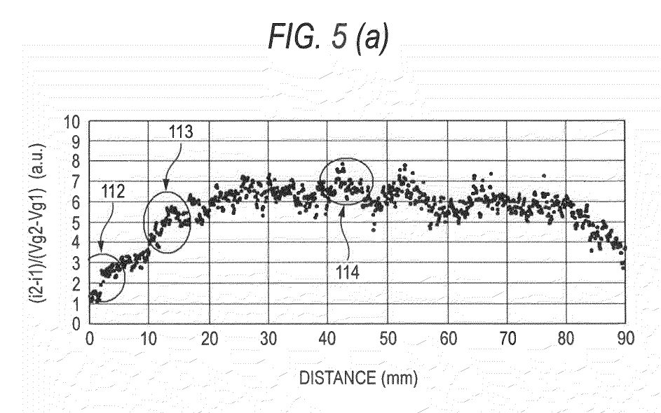

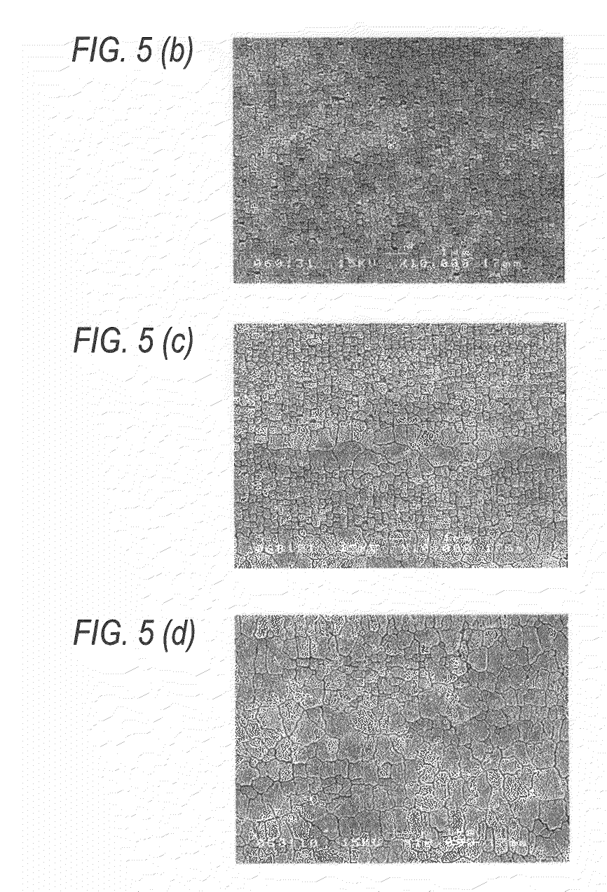

sk or Δsk obtained by using the evaluation device in the first embodiment is evaluated, so that this can be applied to, for example, a method for evaluating the film quality of the poly-crystal semiconductor film and the in-plane distribution thereof. FIG. 5(a) is a graph showing the distribution of sk obtained from the evaluation cells in the first embodiment. Further, to compare observed results of the crystal particles of the poly-crystal semiconductor film in that area, SEM photographs are shown in FIGS. 5(b) to 5(d). In FIG. 5(a), as understood from a fact that as an axis of abscissas, a distance showing a positional relation of the evaluation cells respectively formed on the insulating substrate 1 is used, evaluated results are shown that are obtained from the evaluation cells respectively arranged one dimensionally. However, this is a simplified example and the evaluation cells may be arranged two dimensionally.

In the first embodiment, the values of voltages applied to the scanning wiring 107 are represented by Vg₁=+2V, and Vg₂=+3.5V. Sk in the evaluation cells is calculated respectively from the current values corresponding to the voltages to plot the graph shown in FIG. 5(a). FIG. 5(a) is compared with FIGS. 5(b) to 5(d) as the observed results of the crystal particle. Thus, it is found that as in an area 114, when sk is large, the particle diameter of the crystal is apt to be large as shown in FIG. 5(d). Further, it is found that as in an area 112, when sk is small, the particle diameter of the crystal is apt to be small as shown in FIG. 5(b). Further, it is found that when an unevenness in the particle diameter of the crystal is large as in an area shown in FIG. 5(c), Δsk is apt to be large as in an area 113. Accordingly, it is understood that electrically evaluated results by the evaluation device shown in the first embodiment reflect on the film quality of the poly-crystal semiconductor film.

For the input terminal pad 102 for the scanning wiring 107 that is not connected to the selected evaluation cell 101, an inverse bias (in the case of an n type, a minus, and in the case of a p type, a plus) is preferably applied to the thin film transistor 120 forming the evaluation cell 101. In such a way, a influence by a leak current from other evaluation cells connected to the selected evaluation cell 101 can be reduced so that a more precise evaluation can be realized.

Further, depending on the characteristics of the thin film transistor 120 forming the evaluation cell 101, an optimum voltage value to be applied to the scanning wiring 107 of the selected evaluation cell 101 is different, however, voltage values between which a threshold voltage value is substantially sandwiched are preferably selected. At this time, as an output current outputted from the evaluation cell 101, a value of about 1 μA is obtained, so that the influence of the leak current from other evaluation cells can be substantially neglected. Further, since the variation of an output current to the applied voltage to the scanning wiring 107 is large, a sensitivity of evaluation to the stability or the unevenness of the film quality of the poly-crystal semiconductor film can be improved.

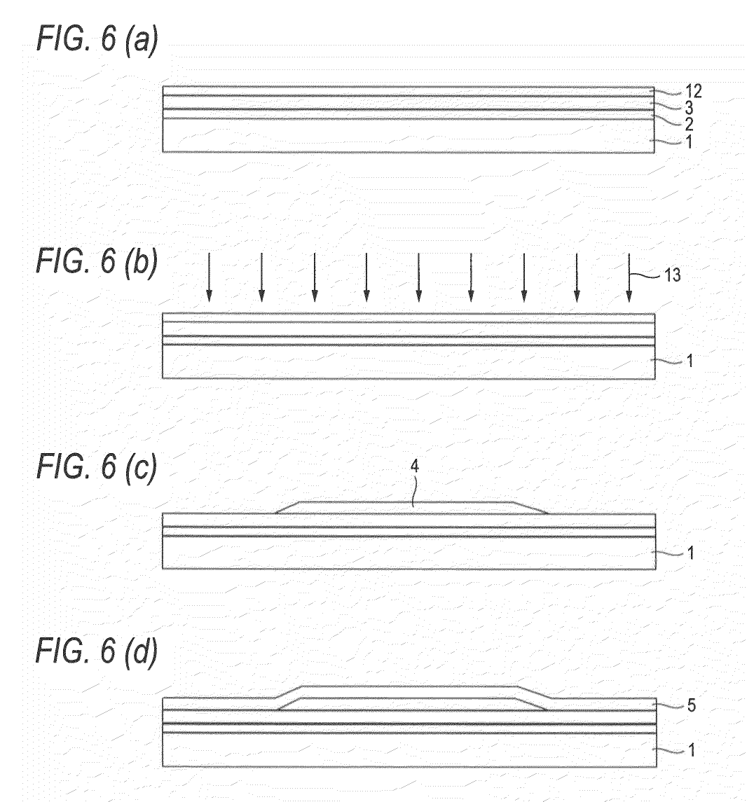

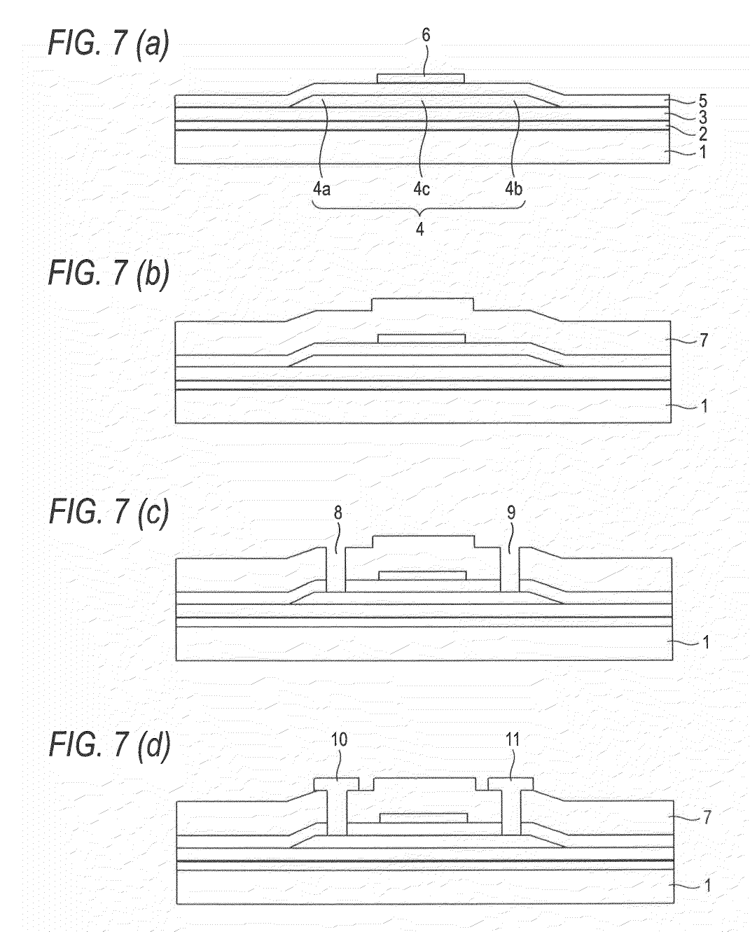

Now, a method for producing the evaluation device in the first embodiment will be described by referring to the drawings. FIGS. 6 and 7 are sectional schematic views showing a method for producing the semiconductor film according to the embodiment. Initially, by referring to FIG. 6(a), a substrate film is formed on the insulating substrate 1 having transmitting characteristics such as a glass substrate or a quartz substrate by using a CVD method. The substrate film is a silicon nitride film (SiN film) 2 or a silicon oxide film (SiO₂ film) 3 as a transmitting insulating film. The substrate film is formed as a substrate of a semiconductor film formed later. In the first embodiment, on the insulating substrate 1 as the glass substrate, the SiN film 2 is formed with the thickness of 40 to 60 nm and the SiO₂ film 3 is formed thereon with the thickness of 180 to 220 nm. Namely, the substrate film has a laminated structure of the SiN film 2 and the SiO₂ film 3. Such a substrate film is provided for the purpose of preventing a movable ion such as Na from being diffused to the semiconductor thin film from the glass substrate. The thickness is not limited to the above-described thickness. The structure is not limited to the above-described structure.

Then, an amorphous semiconductor film 12 is formed on the substrate film by the CVD method. In this embodiment, as the amorphous semiconductor film 12, a silicon film (Si film) is used. The Si film is formed to the thickness of 30 to 100 nm, preferably to the thickness of 60 to 80 nm. The substrate film and the amorphous semiconductor film 12 are preferably continuously formed in the same device or the same chamber. Thus, a contaminant such as boron existing in an ambient atmosphere of atmospheric air can be prevented from being taken in the interfaces of the films and one of factors of the unevenness in characteristics can be removed. Thus, the film quality of the poly-crystal semiconductor film can be more precisely evaluated.

After the amorphous semiconductor film 12 is formed, the amorphous semiconductor film is preferably annealed at high temperature. This process is carried out to reduce a large quantity of hydrogen included in the amorphous semiconductor film 12 formed by the CVD method. In this embodiment, a chamber held in a low vacuum state of nitrogen atmosphere is heated at about 480° C. and the substrate 1 having the amorphous semiconductor film 12 formed is held for 45 minutes. Such a process is carried out, so that when the amorphous semiconductor film 12 is crystallized, even if the temperature rises, the hydrogen is not abruptly released. Thus, the roughness of the surface of the amorphous semiconductor film 12 can be suppressed. In accordance with the above-described processes, a structure shown in FIG. 6(a) is obtained.

Then, a natural oxide film formed on the surface of the amorphous semiconductor film 12 is etched and removed by hydrofluoric acid. After that, while gas such as nitrogen is sprayed to the amorphous semiconductor film 12, laser beams 13 are applied to the amorphous semiconductor film 12 from an upper part as shown in FIG. 6(b). The laser beam 13 is converted to a linear beam form through a prescribed optical system and then applied to the amorphous semiconductor film 12. In this embodiment, as the laser beam 13, a second higher harmonic wave (oscillating wavelength: 532 nm) of YAG laser is used. Further, the laser beam has the linear beam form with a spot of about 60 μm×100 mm. Then, the laser beam scans the amorphous semiconductor film 12 with a feed pitch of 2 μm in a vertical direction relative to the longitudinal direction of the linear beam. In such a way, the amorphous semiconductor film 12 is poly-crystallized. It is to be understood that an excimer laser may be used in place of YAG-2ω laser to evaluate the poly-crystal semiconductor film by the evaluation device shown in the first embodiment.

Then, a resist as a photosensitive resin is applied to the semiconductor film by a spin coating method to carry out a well-known photolithography method for exposing and developing the applied resist. Thus, a photo-resist is patterned to a form to form the thin film transistor as the evaluation element in each evaluation cell. After that, the poly-crystal semiconductor film is etched to remove a photo-resist pattern. Thus, as shown in FIG. 6(c), the poly-crystal semiconductor film 4 is patterned to a desired form.

Then, the gate insulating film 5 is formed so as to cover the entire part of the surface of the substrate. That is, the gate insulating film 5 is formed on the poly-crystal semiconductor film 4. Further, as the gate insulating film 5, the SiN film, the SiO₂ film or the like is used. In this embodiment, as the gate insulating film 5, the SiO₂ film is employed and formed to the thickness of 50 to 100 nm by the CVD method. Further, the surface roughness Ra of the poly-crystal semiconductor film 4 is set to 3 nm or lower and Rmax is set to 30 nm or lower. Further, the poly-crystal semiconductor film 4 is worked to have a section of a tapered form at the end part of the pattern of the poly-crystal semiconductor film 4. Accordingly, the covering characteristics of the gate insulating film 5 are high to greatly reduce an initial failure. Thus, the characteristics of each evaluation cell can be evaluated with good yield. In accordance with the above-described processes, a structure shown in FIG. 6(d) is obtained.

Now, a first electric conductive film is formed for providing the gate electrode 6 for the thin film transistor forming the evaluation cell and the scanning wiring 107 for electrically connecting the evaluation cell. The first electric conductive film may be made of Mo, Cr, W, Al, Ta or an alloy film including them as main components. In this embodiment, Mo is used to form a film with the thickness of 200 to 400 nm to form the first electric conductive film by a sputtering method using a DC magnetron. Then, the formed first electric conductive film is patterned to a desired form by using the well-known photolithography method to form the gate electrode 6 and the scanning wiring 107 (not shown in the drawing). In the first embodiment, the first electric conductive film is etched by a wet etching method using phosphoric acid type etching liquid.

Subsequently, impure elements are introduced to the source area 4a and the drain area 4b of the poly-crystal semiconductor film 4 by using the formed gate electrode 6 as a mask. In the lower part of the gate electrode 6, the channel area 4c to which the impure elements are not introduced is formed. Here, as the impure elements to be introduced, P and B can be used. When P is introduced, an n type TFT can be formed, and when B is introduced, a P type TFT can be formed. Further, when the gate electrode 6 is worked two times for a gate electrode for the n type TFT and for a gate electrode for the p type TFT, the n type and p type TFTs can be formed and divided on the same substrate. Accordingly, a driving circuit for arbitrarily selecting each of the scanning wiring 107 and each of the signal wiring 105 can be formed on the same insulating substrate as that of the evaluation device. Here, the impure elements such as P or B are introduced by using an ion doping method. In accordance with the above-described processes, the gate electrode 6, the source area 4a and the drain area 4b are formed to have a structure shown in FIG. 7(a).

Then, the interlayer insulating film 7 is formed so as to cover the entire part of the surface of the substrate. That is, the interlayer insulating film 7 is formed on the gate electrode 6 and the scanning wiring 107 (not shown in the drawing). In this embodiment, the SiO₂ film is used with the thickness of 500 to 1000 nm to form the interlayer insulating film 7 by the CVD method. Then, the film is held in an annealing furnace heated to about 450° C. in a nitrogen atmosphere for one hour or so. This process is carried out to more activate the impure elements introduced to the source area 4a and the drain area 4b of the poly-crystal semiconductor film 4. In accordance with the above-described processes, a structure shown in FIG. 7(b) is obtained.

Then, the formed gate insulating film 5 and the interlayer insulating film 7 are patterned to a desired form by using the well-known photolithography method. Here, the contact hole 8 and the contact hole 9 reaching the source area 4a and the drain area 4b of the poly-crystal semiconductor film 4 are respectively formed. Namely, in the contact holes 8 and 9, the gate insulating film 5 and the interlayer insulating film 7 are removed and the poly-crystal semiconductor film 4 is exposed. In accordance with the above-described processes, a structure shown in FIG. 7(c) is obtained. Though not shown in FIG. 7(c), a contact hole is also opened to a part where the input terminal pad 102 for the scanning wiring is formed that is electrically connected to the gate electrode 6 through the scanning wiring 107.

Subsequently, a second electric conductive film is formed for forming the source electrode 10, the drain electrode 11 and the wiring. The second electric conductive film may be made of Mo, Cr, W, Al, Ta or an alloy film including them as main components. Further, the second electric conductive film may be formed in a multi-layer structure having these components laminated. In the first embodiment, the electric conductive film has a structure that Mo/Al/Mo are laminated. The thickness of an Al film is set to 200 to 400 nm, and the thickness of Mo films as a lower layer and an upper layer of the Al film is set to 50 to 150 nm. These layers are formed by a sputtering method using a DC magnetron. Then, the formed second electric conductive film is patterned to a desired form by using the well-known photolithography method to form the source electrode 10, the drain electrode 11 and the signal wiring 105 and the signal taking out wiring 106. At the same time, the input terminal pad 103 for the signal wiring and the output terminal pad 104 for the signal taking out wiring may be formed.

In accordance with the above-described processes, in the source area 4a, the source electrode 10 and the signal wiring 105 (not shown in the drawing) connected to the poly-crystal semiconductor film 4 through the contact hole 8 are formed. Further, in the drain area 4b, the drain electrode 11 and the signal taking out wiring 106 (not shown in the drawing) connected to the poly-crystal semiconductor film 4 through the contact hole 9 are formed. Thus, a structure shown in FIG. 7(d) is obtained. Though not shown in the drawing, the input terminal pad 102 for the scanning wiring, the input terminal pad 103 for the signal wiring and the output terminal pad 104 for the signal taking out wiring are also formed.

### Second Embodiment

Now, an evaluation device according to a second embodiment will be described below. In the evaluation device according to the second embodiment, a structure is the same as that of the first embodiment shown in FIG. 1. In the first embodiment, as the evaluation cell, the thin film transistor formed by using the poly-crystal semiconductor film is used as a component element. On the other hand, the second embodiment is characterized in that a thin film transistor is used as a switching element and a capacity element electrically connected in series thereto is also used as a component element of an evaluation cell. Further, also in the evaluation cell according to the second embodiment, a semiconductor film that is poly-crystallized by applying a laser beam to an amorphous semiconductor film formed on an insulating substrate is applied to a thin film transistor, so that the particle diameter of a crystal of the poly-crystal semiconductor film and an unevenness thereof can be evaluated.

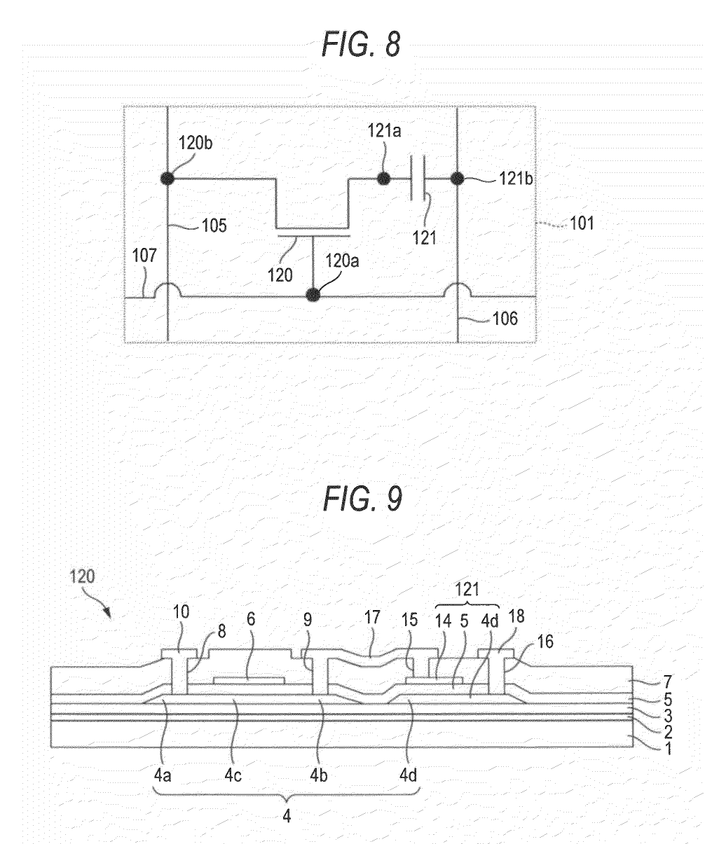

FIG. 8 is an equivalent circuit diagram showing an evaluation cell 101 forming the evaluation device according to the second embodiment. The second embodiment is characterized in that the evaluation cell has a structure that a thin film transistor 120 and a capacity element 121 are connected in series. In FIG. 8, the thin film transistor 120 includes a gate terminal 120a and a source terminal 120b. Between the thin film transistor 120 and the capacity element 121, a drain capacity connecting part 121a is provided. The capacity element 121 includes a signal taking out terminal 121b. Similarly to the first embodiment, the gate terminal 120a and the source terminal 120b are respectively connected to a scanning wiring 107 and a signal wiring 105. Further, the signal taking out terminal 121b of an output side of the capacity element 121 is connected to a signal taking out wiring 106. In such a way, the evaluation cells 101 are respectively connected together by the wiring and arranged like the first embodiment. The evaluation cells may be arranged in one row, namely, one-dimensionally or two-dimensionally in a matrix form.

FIG. 9 shows one example of a sectional structure obtained when the components elements of the evaluation cell 101 are connected together by the thin film transistor 120 and the capacity element 121. In FIG. 9, since the structure of the thin film transistor 120 is the same as that of FIG. 4, an explanation thereof will be omitted. In FIG. 9, the capacity element 121 has a structure that a gate insulating film 5 as a dielectric insulating film is sandwiched in between an upper electrode 14 and a lower electrode 4d. Here, the upper electrode 14 is an electric conductive film formed on the gate insulating film 5 of the thin film transistor 120 and may be formed with the same material as that of a gate electrode 6. Further, as the lower electrode 4d, a poly-crystal semiconductor film 4 is used. As the dielectric insulating film of the capacity element 121, the gate insulating film 5 of the thin film transistor 120 is used, however, a dielectric insulating film suitable for the capacity element 121 may be separately formed.

On the upper part of the capacity element 121, an interlayer insulating film 7 is formed and contact holes 8, 9, 15 and 16 are formed in the interlayer insulating film 7. The contact holes 8, 9 and 16 are formed not only on the interlayer insulating film 7, but also on the gate insulating film 5 and reach the poly-crystal semiconductor film 4. Further, on the interlayer insulating film 7, a source electrode 10, a drain connecting electrode 17 and a signal taking out electrode 18 are formed. Here, the source electrode 10 is connected to a source area 4a through the contact hole 8. Further, the drain connecting electrode 17 is connected to a drain area 4b through the contact hole 9 and further connected to the upper electrode 14 through the contact hole 15. That is, the drain area 4b is connected to the upper electrode 14 through the drain connecting electrode 17. Further, the signal taking out electrode 18 is connected to the lower electrode 4d of the capacity element 121 through the contact hole 16.

Further, though not shown in FIG. 9, the gate electrode 6 and the source electrode 10 respectively correspond to the gate terminal 120a and the source terminal 120b and are connected to the scanning wiring 107 and the signal wiring 105. Further, the signal taking out electrode 18 corresponds to the signal taking out terminal 121b and is electrically connected to the signal taking out wiring 106. The drain connecting electrode 17 corresponds to the drain capacity connecting part 121a. In such a way, the thin film transistor 120 is connected in series to the capacity element 121.

An output as the evaluation cell 101 shown in FIGS. 8 and 9 is transmitted to an output terminal pad 104 for a signal taking out wiring through the signal taking out electrode 18 connected to the lower electrode 4d of the capacity element 121 as in the first embodiment. Therefore, in the evaluation device according to the second embodiment, the same effect as that of the first embodiment is obtained. In the second embodiment, since the evaluation device is basically the same as that of the first embodiment except that as the component element of the evaluation cell, the capacity element is added to the thin film transistor, a description of a method for producing the evaluation device will be omitted.

Now, an evaluation method in the second embodiment will be described below. Here, an explanation will be given to a method for evaluating the film quality of the poly-crystal semiconductor film 4 such as a poly-crystal silicon film provided in the thin film transistor 120 by using the evaluation device according to the second embodiment. Initially, a voltage of Vg₁ (V) is applied to the scanning wiring 107 connected to the evaluation cell 101 located in an area where the film quality is desired to be evaluated from an input terminal pad 102. Further, an applied voltage Vd (V) is scanned relative to the signal wiring 105 connected to the evaluation cell 101 under a measuring frequency f₁ from a signal input terminal, so that the thin film transistor 120 formed in the evaluation cell 101 is turned on and an electric charge is stored in the capacity element 121 connected thereto to change a capacity. Here, to scan the voltage means to apply the voltage having a plurality of different voltage values.

At this time, the capacity of a capacitor of the capacity element 121 is read from the signal taking out wiring 106 connected to the capacity element 121 so that the C-V characteristics of the capacity element 121 as an evaluation element can be measured. Here, the capacity of the capacitor indicates a capacity value obtained when a voltage is applied to the capacitor having an MOS structure of an electric conductive film/a dielectric member/a poly-crystal semiconductor film. In the evaluation device of the second embodiment, a structure including the upper electrode 14, the gate insulating film 5 and the lower electrode 4d corresponds to the capacitor.

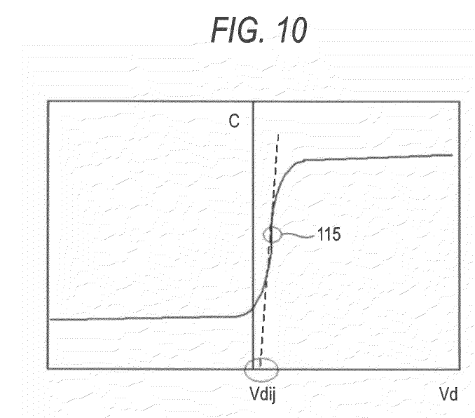

An optimum range of the voltage applied to the signal wiring 105 of a selected evaluation cell is different depending on the characteristics of the capacity element 121 forming the evaluation cell 101, however, a range that includes voltage values by which the capacity element 121 forms an inversion layer is preferably set. In this embodiment, the range of the voltage is set to −2V to +2V and the voltage is scanned for each step of 0.1 V. With reference to FIG. 10 as a C-V characteristic diagram, the range of the voltage applied to the signal wiring 105 of the selected evaluation cell 101 is set so as to include voltage values forming the inversion layer. Thus, an intersection Vdᵢⱼ (i=1, 2 . . . p, j=1, 2, . . . q) of a tangential line at a point where an outputted capacity value of the capacitor shows a maximum change relative to a scanning voltage difference and an axis of scanning voltage indicates an index that the capacity element 121 forms the inversion layer.

Namely, to the p×q evaluation cells arranged two-dimensionally, a voltage is initially respectively applied as each scanning voltage Vdₖ from a minimum scanning voltage Vdₘᵢₙ as a minimum applied voltage to a maximum scanning voltage Vdₘₐₓ as a maximum applied voltage for each scanning voltage step Vdₛₜₑₚ. Here, k of an attached character indicates integers from 1 to n. n indicates figures calculated from below-described equations and corresponds to the number of steps.

n=(Vdₘₐₓ−Vdₘᵢₙ)/Vdₛₜₑₚ [Equation 2]

In the second embodiment, as Vdₛₜₑₚ, 0.1 V is used, however, Vdₛₜₑₚ is not limited to 0.1 V. Here, the scanning voltage difference ΔCₖ of the capacity of the capacitor Cₖ obtained for each scanning voltage Vdₖ, that is, in the second embodiment, the scanning voltage difference ΔCₖ of the capacity of the capacitor Cₖ relative to the change of the scanning voltage 0.1 V is calculated from below-described equations.

ΔCₖ=(Cₖ₊₁−Cₖ)/(Vdₖ₊₁−Vdₖ)

ΔCₖ=(Cₖ₊₁−Cₖ)/0.1 [Equation 3]

Here, by referring to FIG. 10, a point where the capacity of the capacitor Cₖ shows a maximum change relative to the scanning voltage difference, in other words, a point showing the maximum value of the scanning voltage difference ΔCₖ of the capacity of the capacity Cₖ, that is, a maximum change point 115 of the C-V characteristics is obtained to obtain the intersection Vdᵢⱼ of the tangential line at the maximum change point 115 of the C-V characteristics and the axis of scanning voltage. The differences of Vdᵢⱼ of the adjacent evaluation cells or the equality of Vdᵢⱼ of the arranged evaluation cells are compared and evaluated, so that the stability or the unevenness of the film quality of the poly-crystal semiconductor film in an area of a wide range can be electrically evaluated.

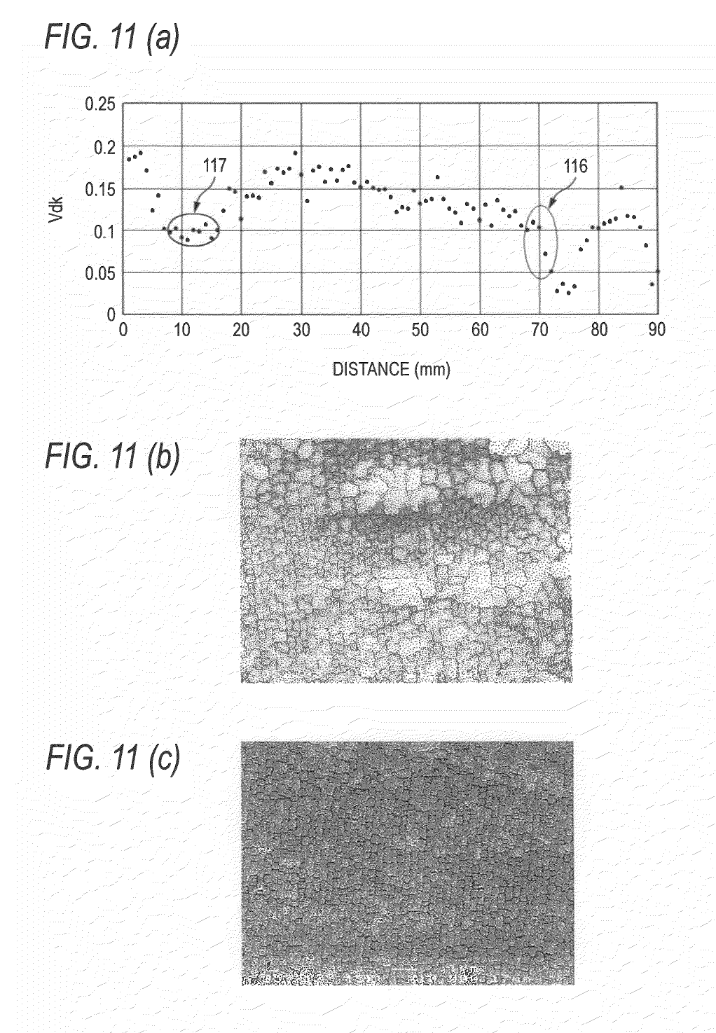

Evaluated results in the second embodiment and one example of observed results of a particle diameter in the area are shown in FIG. 11. FIG. 11(a) is a graph showing a distribution of Vdᵢⱼ obtained form the evaluation cells according to the second embodiment. In the graph, an area 116 enclosed with a circle shows an area where Vdᵢⱼ abruptly changes as a distance changes. That is, the area 116 shows an area where the difference of Vdᵢⱼ of the adjacent cells is large. On the other hand, an area shown by 117 is an area where the change of Vdᵢⱼ is not large with the change of the distance. Further, SEM photographs as the observed results of the crystal particle of the poly-crystal semiconductor film located in the areas 116 and 117 are respectively shown in FIGS. 11(b) and 11(c). In FIG. 11, for the purpose of simplicity, the evaluated results are obtained from the evaluation cells arranged one-dimensionally like the first embodiment, however, it is to be understood that the evaluation cells may be arranged two-dimensionally.

When as a result of comparing the areas 116 and 117 in the graph and FIGS. 11(b) and 11(c), when the unevenness of the particle diameter of the crystal is large as shown in FIG. 11 (b), it is found that the difference of Vdᵢⱼ obtained from the adjacent evaluation cells is apt to be large as in the area 116. Thus, it is understood that the results electrically evaluated by the evaluation device shown in the second embodiment are reflected on the film quality of the poly-crystal semiconductor film. Thus, for example, when a laser beam 13 converged linearly or in a slit form is allowed to scan in a certain direction to poly-crystallize the semiconductor film such silicon, the evaluation cells are arranged so as to include a direction vertical to the scanning direction, so that an influence of the distribution of the energy of the laser beam in the direction along the line or the slit given to an unevenness of crystallization can be grasped, which can contribute to an optimization.

In the second embodiment, as the evaluation cell, not only the thin film transistor, but also the capacity element is connected in series. Accordingly, a factor of a disturbance, for example, the influence of an electric filed from a drain side, such as a short channel effect of the thin film transistor can be reduced to highly accurately evaluate the poly-crystal semiconductor film.

What is claimed is:

1. An evaluation device comprising:
an insulating substrate;
a plurality of evaluation cells arranged on the insulating substrate and respectively having thin film transistors;
a first wiring that applies an electric signal to elements respectively;
a second wiring that takes out electric outputs respectively from the elements; and
a scanning wiring,
wherein the plurality of evaluation cells are respectively electrically connected to the first wiring, the second wiring and the scanning wiring so that the plurality of evaluation cells are respectively connected together, and
wherein terminal pads extending from the second wiring are provided on the insulating substrate.

2. The evaluation device according to claim 1,
wherein the evaluation cells further include capacity elements.

3. The evaluation device according to claim 1,
wherein the evaluation cells are two-dimensionally arranged.

4. The evaluation device according to claim 1,
wherein the evaluation cells are provided with the thin film transistors produced by using a poly-crystal semiconductor film.

5. The evaluation device according to claim 4,
wherein the poly-crystal semiconductor film is a poly-crystal silicon film.

6. The evaluation device according to claim 4,
wherein the poly-crystal semiconductor film is poly-crystallized by applying a laser beam to an amorphous semiconductor film.

7. An evaluation method using an evaluation device, the evaluation device comprising: an insulating substrate; a plurality of evaluation cells arranged on the insulating substrate and respectively having thin film transistors; a first wiring that applies an electric signal to elements respectively; a second wiring that takes out electric outputs respectively from the elements; and a scanning wiring, wherein the plurality of evaluation cells are respectively electrically connected to the first wiring, the second wiring and the scanning wiring so that the plurality of evaluation cells are respectively connected together, and wherein terminal pads extending from the second wiring are provided on the insulating substrate, the evaluation method comprising:
applying a voltage to the thin film transistors through the first wiring;
applying voltages of a plurality of voltage values to the thin film transistors through the scanning wiring; and
measuring electric signals respectively outputted from the evaluation cells relative to the application of the voltages of the plurality of voltage values through the second wiring.

8. The evaluation method according to claim 7,
wherein the electric signal outputted from the evaluation cell is either a current or a capacity of a capacitor.

9. An evaluation method using an evaluation device comprising: an insulating substrate; a plurality of evaluation cells arranged on the insulating substrate and respectively having thin film transistors; a first wiring that applies an electric signal to elements respectively; a second wiring that takes out electric outputs respectively from the elements; and a scanning wiring, wherein the plurality of evaluation cells are respectively electrically connected to the first wiring, the second wiring and the scanning wiring so that the plurality of evaluation cells are respectively connected together, and wherein terminal pads extending from the second wiring are provided on the insulating substrate, the evaluation method comprising:
applying a voltage to the scanning wiring;
applying voltages of a plurality of voltage values to the thin film transistors through the first wiring; and
measuring electric signals respectively outputted from the evaluation cells relative to the application of the plurality of voltages through the second wiring.

10. The evaluation method according to claim 9,
wherein the electric signal outputted from the evaluation cell is either a current or a capacity of a capacitor.

11. An evaluation method using an evaluation device comprising: an insulating substrate; a plurality of evaluation cells arranged on the insulating substrate and respectively having thin film transistors; a first wiring that applies an electric signal to elements respectively; a second wiring that takes out electric outputs respectively from the elements; and a scanning wiring, wherein the plurality of evaluation cells are respectively electrically connected to the first wiring, the second wiring and the scanning wiring so that the plurality of evaluation cells are respectively connected together, and wherein terminal pads extending from the second wiring are provided on the insulating substrate, the evaluation method comprising:
applying a voltage to the thin film transistors through the first wiring;
applying voltages of a plurality of voltage values to the thin film transistors through the scanning wiring;
measuring current values respectively outputted from the evaluation cells relative to the application of the voltages of the plurality of voltage values through the second wiring; and
calculating a value obtained by dividing the difference of the respectively outputted current values by the difference of the plurality of voltage values.

12. An evaluation method using an evaluation device comprising: an insulating substrate; a plurality of evaluation cells arranged on the insulating substrate and respectively having thin film transistors; a first wiring that applies an electric signal to elements respectively; a second wiring that takes out electric outputs respectively from the elements; and a scanning wiring, wherein the plurality of evaluation cells are respectively electrically connected to the first wiring, the second wiring and the scanning wiring so that the plurality of evaluation cells are respectively connected together, and wherein terminal pads extending from the second wiring are provided on the insulating substrate, the evaluation method comprising:
applying a voltage to the thin film transistors through the scanning wiring;
applying voltages of a plurality of voltage values to the thin film transistors through the first wiring; and
measuring the capacities of the capacitors of the capacity elements relative to the application of the plurality of voltages through the second wiring.
